(19) United States
(12) Patent Application Publication
(10) Pub. No.: US 2011/0114163 A1
(43) Pub. Date: May 19, 2011

(54) MULTIJUNCTION SOLAR CELLS FORMED ON N-DOPED SUBSTRATES

(75) Inventors: Michael W. Wiemer, Campbell, CA (US); Homan B. Yuen, Sunnyvale, CA (US); Vijit A. Sabnis, Cupertino, CA (US); Michael J. Sheldon, San Jose, CA (US)

(73) Assignee: Solar Junction Corporation, San Jose, CA (US)

(21) Appl. No.: 12/944,439

(22) Filed: Nov. 11, 2010

Related U.S. Application Data
(60) Provisional application No. 61/262,374, filed on Nov. 18, 2009.

(51) Int. Cl. H01L 31/06

(52) U.S. Cl. 136/255

(57) ABSTRACT

An “n-on-p” type multijunction solar cell structure is disclosed using an n-type substrate for the epitaxial growth of III-V semiconductor material, wherein a “p-on-n” tunnel junction diode is disposed between the substrate and one or more heteroepitaxial layers of III-V semiconductor materials.

### CROSS-REFERENCES TO RELATED APPLICATIONS

The present application claims benefit under 35 USC 119(e) of U.S. provisional Application No. 61/262,374, filed on Nov. 18, 2009, entitled “MULTIJUNCTION SOLAR CELLS FORMED ON N-DOPED SUBSTRATES,” the content of which is incorporated herein by reference in its entirety.

### STATEMENT AS TO RIGHTS TO INVENTIONS MADE UNDER FEDERALLY SPONSORED RESEARCH AND DEVELOPMENT

NOT APPLICABLE

### REFERENCE TO A “SEQUENCE LISTING,” A TABLE, OR A COMPUTER PROGRAM LISTING APPENDIX SUBMITTED ON A COMPACT DISK

NOT APPLICABLE

### BACKGROUND OF THE INVENTION

This invention relates to structures and techniques for construction of solar cells based on III-V materials, such as gallium and arsenide. More particularly, this invention relates to the problem of forming reliable electrically conductive contacts for electrical terminals for devices or structures incorporating III-V materials.

Conventional or known III-V GaAs-based solar cells can be divided into three parts—a lower part, a middle part, and an upper part, as shown in cross-sectional representation in FIG. 1. The lower part 10 is the growth substrate on which various layers of the device are sequentially grown. In a typical multijunction solar cell, the lower part 10 is generally a p-GaAs or p-Ge substrate on which the remaining layers are grown. In addition, this lower part may incorporate a back or bottom electrical contact 11 to conduct electricity from the cell to a load of some kind. The middle part 20 represents the heteroepitaxial III-V device layers, forming at least one p-n junction completely contained within the middle region. The upper part 30 represents semiconductor and metal layers required to complete the electrical contact to the device, in addition to an anti-reflection coating (ARC) layer that is often included in such a device.

Generally, the metal and semiconductor layers in the upper part 30 are patterned into a grid of lines 40 as shown in FIG. 3. Many variants are possible on the pattern of grid lines. The metal stack used for the grid must be sufficiently thick to conduct the solar-generated current produced by the cell with little resistance. Metal stack thicknesses on the order of 5 μm containing mostly silver or gold are typical. There are many different designs of III-V solar cells described in the literature and the prior art, using a variety of materials and manufacturing techniques. A schematic cross-sectional representation of a two junction solar cell appears in FIG. 2.

The layer that faces the sun is referred to as the uppermost or top layer of the uppermost junction. Most solar cell junctions consist of a thin n-type emitter region on top of a thicker p-type base region (an “n-on-p” type structure). For the cell to work properly, all junctions within the III-V stack must have the same orientation. Thus, if one junction is an ‘n-on-p” type, all junctions in the cell must the same. Junctions within the multijunction solar cell stack may include back and front surface fields. Tunnel junctions may connect the various sub-cell p-n junctions.

Because of the need for a uniform orientation of the junctions within the III-V stack, a standard “n-on-p” type solar cell is typically grown on a p-doped substrate such as p-GaAs or p-Ge. The substrate in such cells often is used as the bottom layer of the lowermost junction. However, p-doped GaAs substrates are typically more expensive than the alternative n-type or semi-insulating (SI) varieties. It would be desirable, therefore, to reduce the production cost of “n-on-p” type solar cells by using a lower cost n-doped growth substrate. To do so directly, however, would create a reverse orientation of the lowermost junction, thus causing the solar cell to not operate properly.

### SUMMARY OF THE INVENTION

According to the invention, a method is provided for using n-GaAs (or other n-doped semiconductor material) as the substrate for “n-on-p” type solar cell designs by depositing a “p-on-n”tunnel junction diode as the first layer of material above the substrate and depositing the entirety of the III-V stack above the tunnel diode. Other layers may be grown between the substrate and the first tunnel junction, provided the type of doping of the other layers is either n-type or undoped. This first tunnel junction, like the other tunnel junctions in the solar cell, operates in an electrically non-rectifying regime. Electrically, the tunnel junction operates like a low resistance resistor and does not block current flow.

The invention will be better understood by reference to the following detailed description in connection with the accompanying drawings.

### BRIEF DESCRIPTION OF THE DRAWINGS

FIG. 1 is a cross-sectional diagram representing a generalization (prior art) of a solar cell into a lower, middle and upper part on a metal layer.

FIG. 2 is a cross-sectional diagram representing a generalization (prior art) of a double junction, n-on-p type solar cell stack.

FIG. 3 is a top plan view schematically depicting a (prior art) metal grid layout.

FIG. 4 is a cross-sectional view in schematic form of a p-on-n type device according to the invention where a tunnel junction has been inserted between the substrate and the III-V heteroepitaxial solar cell device layers, representative of a third-junction, four-junction or five-junction solar cell.

FIG. 5 is a graphical representation of a current-voltage characteristic of an InGaP/GaAs multijunction solar cell with light consisting of a simulated “1-sun” solar spectrum applied to the solar cell.

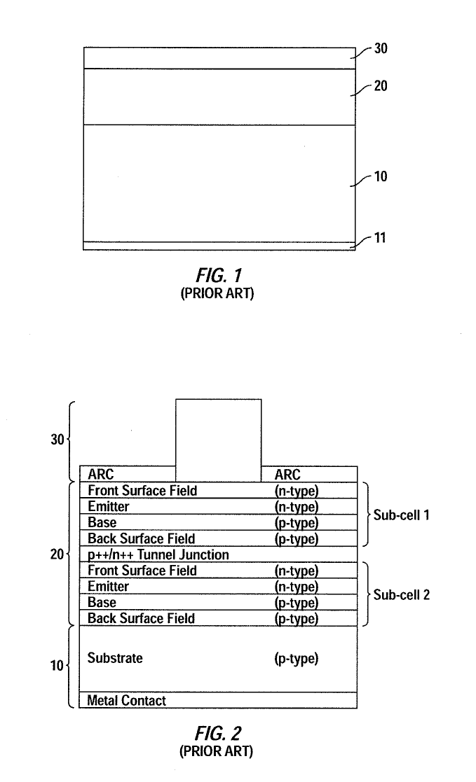

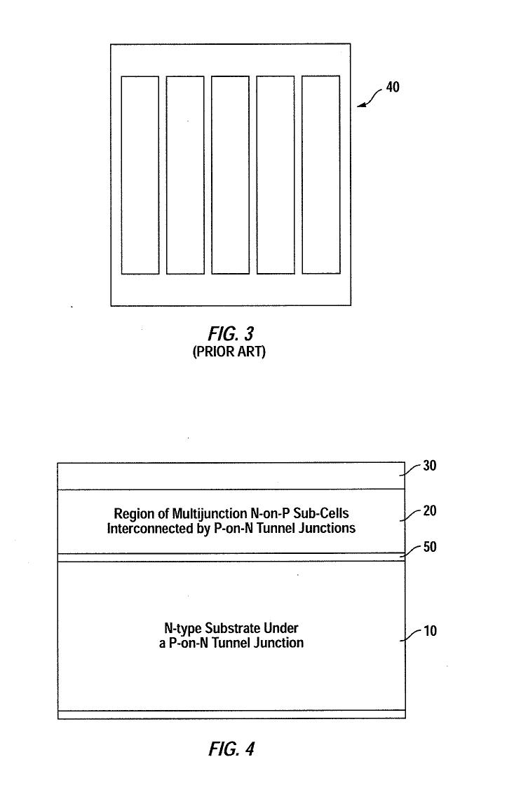

### DETAILED DESCRIPTION OF THE INVENTION

FIG. 4 illustrates the invention. An “n-on-p” type solar cell device includes an upper part 30, middle part 20, and an n-type substrate as lower part 10. The additional tunnel junction 50 is deposited between the lower part 10 and middle part 20 and essentially inverts the n-doped surface of the substrate to a p-doped material. A standard n-type semiconductor and metal contact 11 can be made to the n-type substrate 10.

A specific embodiment uses a dilute nitride sub-cell above the tunnel junction 50, rendering the solar cell capable of absorbing longer wavelength energies without having to rely on use of the substrate as part of the sub-cell structure. This embodiment is particularly advantageous as it combines long wavelength sub-cell capability with low cost n-type GaAs substrates, where all base and emitter layers in the solar cell are lattice matched to one another. A dilute nitride is generally considered to be a Type-III-V semiconductor alloy having less than 5% nitrogen content. The term longer wavelengths in this context refers to wavelengths corresponding to energies of less than 1.42 eV, which is equivalent to the bandgap of pure GaAs, or greater than approximately 870 nm wavelength. Lattice matched layers have a crystal structure which is coherent and does not relax or break down from layer to layer despite the possibility of strain in the layers.

The bandgap and lattice constant of a dilute nitride can be changed independently through proper choice of composition, allowing dilute nitrides, for example, to be lattice matched to Gallium Arsenide substrates, and have an optimal bandgap for a particular device design. For example, in the case of a triple junction solar cell, the optimal bandgap of the longest wavelength junction is around 1 eV (0.93 eV to 1.05 eV). Such a bandgap can be achieved using dilute nitride material while maintaining lattice match to GaAs. This type of triple junction solar cell may have a second junction and a third junction that are constructed of Gallium-Arsenide and Indium-Gallium-Phosphide. In this case, the bulk of all of the n-on-p junctions can be lattice matched to the substrate.

Another specific embodiment involves the use of a Silicon-Germanium alloy as the longest wavelength absorbing junction. Silicon-Germanium material can be readily lattice matched to a GaAs substrate. Lattice matching to GaAs is achieved through the addition of approximately 2% Silicon to Germanium. The Silicon is added to Germanium specifically to promote lattice matching of the sub-cell to a Gallium-Arsenide substrate. Such a material has a bandgap close to 0.7 eV. Triple junction devices comprising a Silicon-Germanium sub-cell can be constructed similarly to the above mentioned dilute nitride based structure.

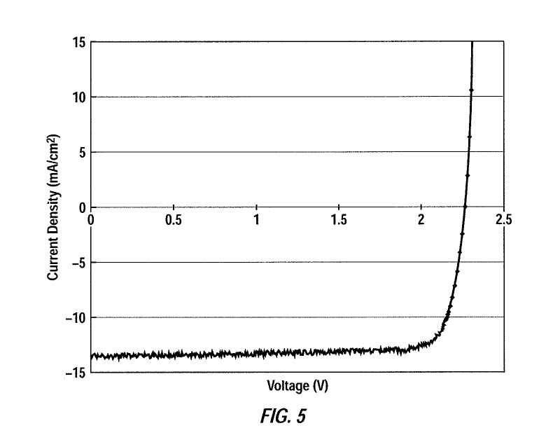

An “n-on-p” type solar cell fabricated on an n-GaAs substrate utilizes this approach. FIG. 5 shows a current-voltage (IV) curve from such a device operating under approximately one sun of optical power. This demonstration device was a double junction solar cell with a design similar to that shown in FIG. 2, but with an extra tunnel junction between substrate 10 and stack 20 as illustrated in FIG. 4. This bottom most tunnel junction was formed from p++GaAs and n++GaAs. The device tested achieved a 1-sun short circuit current of 13.4 mA/cm2, an open circuit voltage of 2.26V, and a fill factor>85%, clearly demonstrating the viability of this design.

The invention will work with many different multijunction devices having from 1-to-n junctions (where n>1). Those skilled in the art will readily understand that solutions applicable to a two or three junction device will also be useful for more or fewer junctions, such as a four-junction solar cell or a five junction solar cell. The invention can be used with many different materials and configurations that are used to make solar cells and solar cell junctions, including without limitation dilute nitride materials, metamorphic InGaAs layers, quantum dots, quantum wells and the like. The invention described herein is applicable to any generalized “n-on-p” type solar cell device in which all solar absorbing junctions are contained within the stack 20 shown in FIG. 2. The invention is useful in lattice matched structures. The substrate 10 is not part of a solar absorbing junction. Thus, this disclosure is meant to be representative and illustrative, not a dispositive discussion of all the ways that those skilled in the art might use the inventions.

The invention has been explained with reference to specific embodiments. Other embodiments will be evident to those of skill in the art. It is therefore not intended that the invention be limited, except as indicated by the appended claims.

What is claimed is:

1. A device comprising:
a substrate of n-doped semiconductor material in electrical contact with a metal conductor;
a p-on-n tunnel junction diode disposed above the substrate;
one or more n-on-p junctions disposed above the tunnel junction diode;
a metal grid in electrical contact with the uppermost layer of semiconductor;
together forming a photovoltaic device.

2. The device according to claim 1 wherein the uppermost layer of semiconductor, in contact with the metal grid, is n-type.

3. The device according to claim 1 wherein said tunnel junction diode uses p++GaAs on n++GaAs.

4. The device according to claim 1 wherein the formed photovoltaic device is a triple junction solar cell.

5. The device according to claim 4 wherein at least one of the n-on-p junctions has a bandgap of approximately 1 eV, or between 0.93 eV and 1.05 eV.

6. The device according to claim 5 wherein at least a first junction is comprised of a dilute nitride material lattice matched to the substrate.

7. The device according to claim 6 wherein at least a second junction and a third junction are comprised of Gallium-Arsenide and Indium-Gallium-Phosphide and all the n-on-p junctions are lattice matched to the substrate.

8. The device according to claim 7 wherein the substrate is comprised of n-type Gallium-Arsenide.

9. The device according to claim 5 wherein said approximately 1 eV junction is comprised of a material which is not lattice matched to the substrate.

10. The device according to claim 4 wherein at least one junction is comprised of a Silicon-Germanium material lattice matched to the substrate.

11. The device according to claim 1 wherein the formed photovoltaic device is a four junction solar cell.

12. The device according to claim 11 wherein at least a first junction is comprised of a dilute nitride material lattice matched to the substrate.

13. The device according to claim 1 wherein the formed photovoltaic device is a five junction solar cell.

14. The device according to claim 13 wherein at least a first junction is comprised of a dilute nitride material lattice matched to the substrate.

15. The device according to claim 1 wherein said one or more n-on-p junctions include materials identified in Groups III and V of the Periodic Table.
